(19) United States
(12) Patent Application Publication
(10) Pub. No.: US 2024/0312810 A1
(43) Pub. Date: Sep. 19, 2024

(54) ENCLOSURE CONSTRUCTIONS FOR REACTORS USED IN SEMICONDUCTOR FABRICATION PROCESSING

(71) Applicant: ASM IP Holding B.V., Almere (NL)

(72) Inventor: Mun Peow Wong, Phoenix, AZ (US)

(21) Appl. No.: 18/603,366

(22) Filed: Mar. 13, 2024

Related U.S. Application Data
(60) Provisional application No. 63/452,480, filed on Mar. 16, 2023.

(51) Int. Cl. H01L 21/67; C23C 16/455; C23C 16/52

(52) U.S. Cl. CPC H01L 21/6719; C23C 16/45565; C23C 16/52; H01L 21/67017; H01L 21/67248

(57) ABSTRACT

Enclosure constructions comprise a housing configured to enclose an upper chamber of reactors, associated showerheads, and material source or gas lines of a semiconductor fabrication assembly. A heating element and fan impeller are inside the housing. A motor is disposed outside of the housing and is operatively coupled to the fan impeller. A controller is used to operate one or both of the heating element and the motor to produce heated air that is distributed within the housing. The heated air distributed in the housing has a uniform temperature, minimizes or eliminates the number of heat zones in the assembly, and heats the material source lines to eliminate the need for heating jackets, associated controllers, and associated insulation. The enclosure construction reduces the complexity and spatial packing density of the assembly to facilitate assembly, installation, and maintenance of the assembly, and improves the operating thermal efficiency of the assembly.

### CROSS-REFERENCE TO RELATED APPLICATIONS

This application is a nonprovisional of, and claims priority to and the benefit of, U.S. Provisional Patent Application No. 63/452,480, filed Mar. 16, 2023 and entitled “ENCLOSURE CONSTRUCTIONS FOR REACTORS USED IN SEMICONDUCTOR FABRICATION PROCESSING,” which is hereby incorporated by reference herein.

### FIELD

Enclosure constructions as disclosed herein relate to reactors used for semiconductor fabrication processing and, more specifically, to showerheads used with such reactors, wherein the enclosure constructions are specially designed to provide a uniform desired temperature external to the showerheads, thereby avoiding the existence of different heat zones external to the showerheads that operates to ease assembly/maintenance issues and promote thermal efficiency during semiconductor fabrication processing.

### BACKGROUND

Showerheads are used in reactors during semiconductor fabrication for the purpose of dispensing one or more desired materials onto a substrate or wafer disposed in the reactor. In an example, the showerhead comprises a perforated or porous planar surface to dispense reactant gases more-or-less uniformly over a parallel planar surface of the wafer. In an example, the material that is dispensed may be in the form of a vapor and the process may be one of chemical vapor deposition, plasma deposition, or the like. Such showerhead comprises a source or feed line that provides the material to be dispensed that is heated using heater jackets and the like to maintain the feed material, e.g., in gas form, at desired temperature. Additionally, such showerhead may itself be heated, having one or more heater zones.

Equipment used for semiconductor fabrication processing comprises an assembly of more than one reactors and associate showerheads placed in close proximity to one another, e.g., in a base platform or the like for the purpose of processing of multiple semiconductors in a manner that is spatially efficient. In such an assembly, the reactors and associated showerheads are mounted relatively close to one another and include heated feed lines running to each showerhead along with other lines that may be used to heat the showerheads themselves and/or that may be used to heat the reactors. Accordingly, in such an assembly there may be a number of different heater zones associated with the different showerheads, feed lines, and other heated lines, wherein the use of such heated feed and other lines that are all in close proximity to one another that adds to the complexity and time associated with installing, maintaining, and/or repairing/replacing parts in the assembly. Further, because the components of such assembly are open to the external environment, such assembly has a large degree of heat loss and resulting thermal inefficiency.

It is, therefore, desired that a construction be developed for used with reactors and showerheads as disclosed above that is configured to reduce the number of different heat zones and equipment needed for heating for the purpose of reducing the complexity of such assemblies comprising reactors and associated showerheads to also promote installation, maintenance, and/or repair/replacement of parts used in such assemblies. It is further desired that such construction be configured in a manner that provides a uniform heating external to the reactors and associated showerheads at a controlled temperature to promote improved thermal efficiency as compared to the above described known assembly of reactors and associated showerheads.

### SUMMARY

Enclosure constructions as disclosed herein are in the form a heating assembly configured for use with a plurality of reactors used for semiconductor fabrication. In an example, the heating assembly comprises a housing that is configured to fit over and enclose at least an upper chamber of the plurality of reactors and associated showerheads and material source lines, e.g., gas lines, used for semiconductor fabrication. In an example, a heating element is disposed in the housing and is configured to provide heat within the housing. In an example, a fan impeller is disposed in the housing and is configured to provide air flow that distributes and circulates the heat produced by the heating element throughout the housing. In an example, the heating element and the fan impeller are operated to provide temperature uniformity within the housing. In an example, the housing may be thermally insulated to minimize heat loss from inside the housing to an external environment. In an example, a motor is disposed outside of the housing and is operatively connected with the fan impeller. In an example, the plurality of reactors is attached to a base or a base structure. In an example, the housing is in the form of a box having side walls attached to a top lid forming an enclosure, wherein the housing include an open end that is formed by the side walls and that is attached with the base.

In an example, the housing comprises one or more openings for accommodating passage of material source pipes external to the housing therein. The heating assembly may comprise a sensor disposed in or out of the housing that is configured to monitor or determine the temperature of the heated air circulated within the housing. The heating assembly may comprise a controller for adjusting one or both of the heat produced by the heating element and a speed of the fan impeller. The housing may comprise one or more elements disposed therein for channeling the heated air moved by the fan within the housing in a desired direction, wherein the one or more elements may be in the form of one or more cowlings or baffles that direct the heated air moved by the fan to the one or more showerheads.

Such enclosure constructions function to reduce the number of heat zones and heating equipment associated with the same (that are present in a semiconductor fabrication assembly comprising reactors, associated showerheads, and associated material feed lines) by providing a contained environment within which heated air having a uniform temperature is circulated. This enables the material source or gas lines to be used without the need for heater jackets, related controllers, and associated insulation, which reduces the complexity and spatial packing density of parts and elements as used with such semiconductor fabrication assembly that eases and reduces the time associate with assembling, installation, and maintaining such semiconductor fabrication assembly. Further, such enclosure constructions function to minimize or eliminate thermal or heat loss from such semiconductor fabrication assembly to the external environment, thereby improving the thermal efficiency associated with the operation of such assembly.

### BRIEF DESCRIPTION OF THE DRAWINGS

These and other features and advantages of enclosure constructions used for semiconductor fabrication processing as disclosed herein will be appreciated as the same becomes better understood by reference to the following detailed description when considered in connection with the accompanying drawings where:

FIG. 1 perspective view of a prior art assembly comprising a number of reactors and associated showerheads as combined together for use in semiconductor fabrication processing;

FIG. 2 is a perspective view of an assembly comprising an example enclosure construction as disclosed herein enclosing and providing a controlled temperature environment to a number of reactors and associated showerheads as combined together and for use in semiconductor fabrication processing;

FIG. 3 is a cross-sectional view of an example enclosure construction as disclosed herein as used to enclose and provide a controlled temperature environment to a number of showerheads used in semiconductor fabrication processing; and

FIG. 4 is a cross-sectional view of the example enclosure construction of FIG. 3, illustrating example flow paths of temperature controlled air therein.

### DETAILED DESCRIPTION

Enclosure constructions as disclosed herein are generally configured to enclose one or more reactors and associated showerheads and associated source lines to the showerheads as used for semiconductor fabrication processing. In an example, the enclosure construction comprises a heat source and a fan impeller that is disposed therein and that are operated to distribute heated air within the enclosure in a manner that provides a uniform temperature therein. In an example, enclosure constructions as disclosed herein are configured to enclose an assembly of more than one reactors and associated showerheads and source lines to thereby reduce the number of heat zones within the assembly. Such enclosure constructions as disclosed herein avoids the need to use heated source lines, thereby reducing number of parts in the assembly and the complexity and time associated with assembling, maintaining and/or repairing/replacing the parts within the assembly.

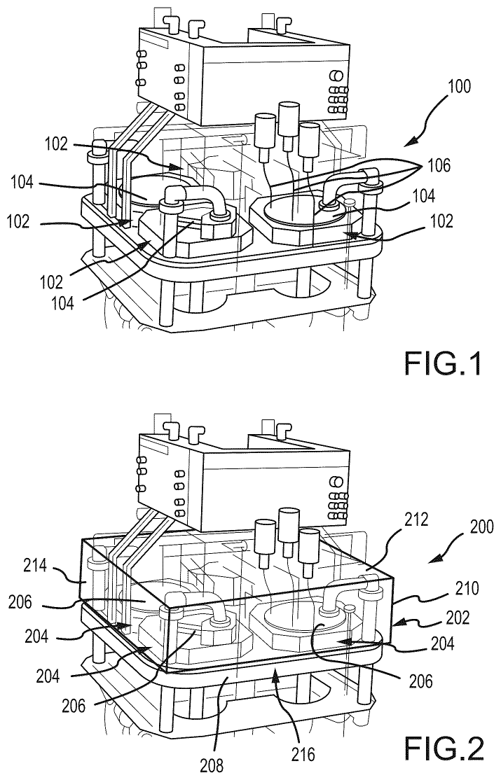

FIG. 1 illustrates a known assembly or apparatus 100 used for semiconductor fabrication processing of multiple semiconductors comprising four reactors 102, and four associated showerheads 104 that are arranged in close proximity to one another. Such known assembly or apparatus 100 comprises a plurality of source lines 106 that are routed to each of the associated showerhead for transporting a desired source material from a storage vessel (not shown) located outside of the assembly to the showerheads. The source lines 106 are heated and are constructed comprising heater jackets (not shown) for purposes of maintaining the source material at a desired elevated temperature, insulation (not shown) disposed around the heater jackets, and heater jacket controllers for purposes of maintaining the source lines 106 at the desired heated temperature. Because of the close proximity of the reactors 102 and associated showerheads 104 and heated source lines 106 within the assembly, this results in a number of source line heater zones in close proximity to one another. In an example, the showerheads are also heated that further contributes to the number of heater zones in the assembly. The large number of heater zones in a small, confined area means a lengthier showerhead assembly time, maintenance, repair/replacement time, and a more difficult routing of lines and wiring within the assembly. Also, because the components within the assembly 100 are open to the environment, such assembly 100 results in a high level of heat loss to the environment and associated thermal inefficiency.

FIG. 2 illustrates an assembly or apparatus 200 used for semiconductor fabrication comprising an example enclosure construction 202 as disclosed herein. In an example, assembly comprises a number of reactors 204 and associated showerheads 206, and in a particular example the assembly comprises four reactors 204 and associated showerheads 206. In an example, the enclosure construction 202 is configured to fit over a periphery of a base structure 208 of the assembly 200 upon which at least a top portion of the reactors 204 and an entire portion of the associated showerheads 206 are disposed. In an example, the reactors 204 are attached or mounted to the base structure 208 of the assembly 200.

In an example, the enclosure construction 202 comprises a housing 210 that comprises a closed top lid or cover 212 with side walls 214 connected with and extending downwardly from the top lid 212. In an example, wherein the top lid 212 has a square shape with four sides, the housing comprises four side walls 214 extending therefrom. The housing 210 comprises an open end 216 opposite the closed top lid 212 that is formed by ends of the side walls 214 opposite the closed top lid 212. In an example, the housing open end 216 is configured to connect or attach with the assembly base structure 208 to enclose the contents of the assembly 200 above the base structure 208 within the housing 210. While a particular configuration of the enclosure construction 202 has been disclosed, it is to be understood that enclosure constructions may be configured differently depending on the assembly to be enclosed and that all such different configurations of enclosure constructions are intended to be within the scope of enclosure constructions and assemblies comprising the same as disclosed herein.

In an example, the enclosure construction 202 may be formed from any type of structurally rigid material capable of maintaining its mechanical properties at elevated temperatures associated with the operating temperatures of the reactors and the associated showerheads. In an example, the enclosure construction may be formed from a metallic material or a polymeric material. In an example, the enclosure construction is formed from a metallic material such as multi-metal steel, stainless steel, aluminum, and the like. In a particular example the metallic material is stainless steel. The wall thickness of the enclosure construction will vary on the type of material selected to form the enclosure construction as well as the particular semiconductor fabrication process parameters being used. The dimensions of the enclosure construction, e.g., the width and length of the top lid 212 and the width and length of the side walls 214 will vary depending on the dimension of the assembly base structure 208 and the components that are disposed therein or thereon. In an example, the enclosure construction top lid 212 is sized and configured similar to that of the assembly base structure 208, e.g., along a periphery of the base structure 208, and the side walls 214 are sized and configured to provide a desired attachment or closed fit with the assembly base structure 208 while providing a sufficient inside height within the enclosure construction to both clear the components of the assembly disposed on or extending upwardly from the assembly base structure 208 and provide a desired thermal flow (heated air circulation) environment therein as better describe below.

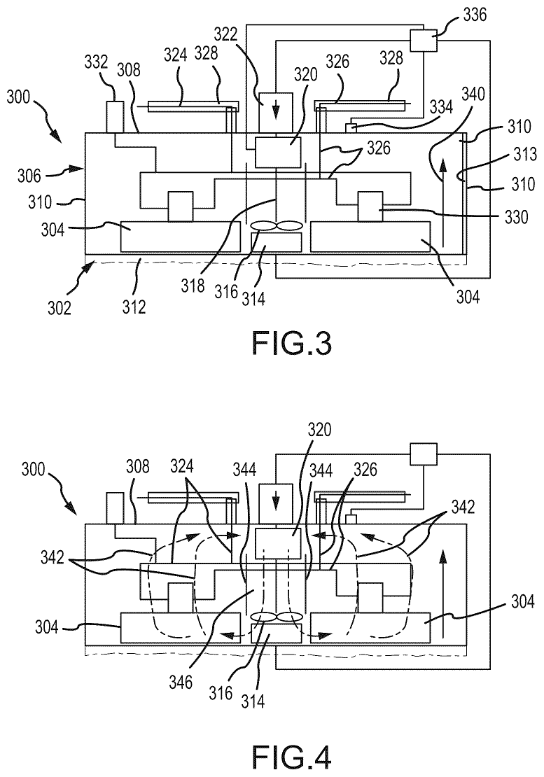

FIG. 3 illustrates an example enclosure construction 300 as attached or fit over an apparatus or assembly 302 comprising reactors (not shown) and associated showerheads 304. The enclosure construction comprises a housing 306 comprising a top lid or cover 308 disposed along an upper portion of the housing and side walls 310 connected with and extending downwardly from the top lid 308. In this view, three of four side walls 310 are shown; namely, a back side wall 310, and two opposed side walls (wherein the cross-sectional view does not illustrate the front side wall). Bottom portions of the side walls 310 are attached or connected with the base structure 312 of the assembly or apparatus as described above and also illustrated in FIG. 2. In an example, the bottom portions of the side walls 310 and the base structure 312 are connected or fitted together to provide an air-tight attachment therebetween. In an example, a sealing element or the like (not shown) may be used, e.g., interposed between interfacing surfaces of the side walls 310 and the base structure 312 to assist in providing such attachment. Configured in this manner, the enclosure construction 300 covers and encloses the components in the assembly or apparatus 302 positioned on or above the base structure 312 from the external environment.

In an example, the enclosure construction 300 may be thermally insulated to prevent or minimize thermal transfer or heat loss from within the enclosure construction to the external environment, and such thermal insulation may come from the material itself that is used to form the enclosure construction housing top lid 308 and side walls 310. Alternatively or in addition, a thermal insulating material 313 may be provided along inside surfaces of one or more of the enclosure construction top lid 308 and side walls 310. Example thermal insulating materials suitable for use as disclosed herein include non-preformed materials that can be applied as a coating by spray, brush or other means to form a thermal insulating layer on inside surfaces of the enclosure construction 300. Examples of such non-preformed materials suitable for forming a thermal insulating coating layer include fluoropolymeric materials such as perfluoroalkoxy (PFA), polytetrafluoroethylene (PTFE), and the like; and other polymeric materials having thermal insulating properties such as polyoxymethylene (POM), and the like. Suitable thermal insulating materials also include those that are preformed and provided in the form of a sheet, panel, or plate of material that is attached mechanically or by adhesive bond or the like to the inside surface of the enclosure construction 300. Examples of such preformed thermal insulating material include silicones, such as silicone-rubber and the like, that may or may not be in the form of a foam, e.g., an open-pore foam. While a few particular examples of materials useful for forming thermal insulating materials have been described, it is to be understood that other materials having thermal insulating properties may be used and all such other materials are understood to be within the scope of enclosure constructions as disclosed herein. The particular thickness of the thermal insulating material can and will vary depending on a variety of factors. In an example, the thermal insulating material may have a thickness of from about 0.5 mm to 100 mm, from about 5 mm to 50 mm, and from about 10 to 30 mm.

In the illustrated example, the enclosure construction 300 is shown to enclose two showerheads 304 that are positioned side-by-side of one another. As this is a cross-sectional view, the enclosure construction 300 is configured to enclose four showerheads (as illustrated in FIG. 2), wherein the other two showerheads, e.g., the front two showerhead are not shown). However, it is to be understood that enclosure constructions as disclosed herein may be configured to enclose any number of showerheads depending on the particular semiconductor fabrication assembly or apparatus being used and the number of reactors in the assembly.

In an example, the enclosure construction 300 comprises a heating element 314 positioned near the bottom of the enclosure construction 300 and that may be attached to the base structure 312 of the assembly 300. In an example, suitable types of heating elements 314 that may be used with the enclosure construction 300 as disclosed herein include those configured for heating the air inside of enclosure construction. In an example, the heating element 314 is an air heater. While a single heating element has been shown, it is to be understood that more than one heating element may be used depending on the particular semiconductor fabrication assembly or apparatus, e.g., depending on the number and arrangement of the different reactors and associated showerheads. In an example, the heating element is configured to be electrically powered and generate heated air having a temperature of from about 50 to 200° C., and in a particular example generate heated air having a temperature of approximately 120° C. As better described below, the heating element 314 is positioned at a bottom position of the enclosure construction 300 for the purpose of directing heated air first to the showerheads 304 that are positioned adjacent to the heating element 314 so that air being circulated to the showerheads is first heated to reduce the temperature gradient caused by the thermal energy being generated by the showerheads for subsequent upward heated air circulation into the remaining volume inside of the enclosure construction 300 above the showerheads 304.

A fan impeller 316 is located adjacent the heating element 314 and is configured and positioned to cause air inside of the enclosure construction 300 to be directed to the heat element 314 (as better disclosed below and illustrated in FIG. 4), in this case to cause air to flow downwardly over the heating element 314. The fan impeller 316 is of conventional design comprising a number of blades configured to cause air to flow in a desired direction when the fan impeller 316 is rotated during operation. The fan impeller 316 is connected to a shaft 318 that extends axially upward from the fan impeller in the enclosure construction 300.

In an example, the enclosure construction 300 comprises an optional cooling element 320 that is positioned and attached near the enclosure construction top lid 308 and that is used to cool the heated air that is circulated inside of the enclosure construction 300 in the event that the heated air exceeds a desired set temperature. In an example, the cooling element 320 is provided in the form of an air-water heat exchanger. However, it is to be understood that other types of cooling elements may be used that function to cool the heated air circulating in the enclosure construction 300. In the example where the cooling element 320 is an air-water heat exchanger, the shaft 318 that is connected to the fan impeller 316 extends to the air-water heat exchanger 320 and may be connected with an impeller or the like (not shown) to circulate the water in the cooling element 320. In an example, the shaft 318 extends from the cooling element 320 axially upward and through an opening in the enclosure construction top lid 308.

A motor 322 is positioned and attached to an outside surface of the enclosure construction top lid and is operatively connected to the shaft 318. It is desired that the motor be positioned outside of the enclosure construction so that it is not affected by the heated air being circulated therein. In an example, the motor 322 is electrically powered and is configured when actuated to rotate the shaft 318 to cause the fan impeller 316 to produce a desired air flow circulation within the enclosure construction 300.

In an example, material source lines 324 and 326 (that function to transport material stored outside of the semiconductor fabrication apparatus to the showerheads for use in the associated reactors during semiconductor fabrication processing) are directed from outside of the enclosure construction 300 into the enclosure construction 300 and to the showerheads 304. In an example, material source lines 324 and 326 that are disposed outside of the enclosure construction 300 may be heated and be configured to include heater jackets 328 or the like that are operated to transport the material to the enclosure construction 300 at a desired elevated or heated temperature. The enclosure construction 300 comprises openings through the top lid 308 that are positioned and sized to accommodate passage of material source lines 324 and 326 therethrough. A feature of the enclosure construction 300 as disclosed herein is that it is specially constructed and configured to circulate heated air within the enclosure construction that eliminates the need to use heat jackets to heat the material source lines 324 and 326 inside of the enclosure construction 300. Accordingly, the material source lines 324 and 326 are routed inside of the enclosure construction 300 to each of the showerheads 304 in a manner that avoids tight spatial packing as would otherwise exist if heat jackets were needed.

In an example, a point-of-use valve manifold (PVM) 330 is used with each of the showerheads 304 for the purpose of distributing the two different materials from the source lines 324 and 326 to the showerheads. While a particular example of material source lines 324 and 326 as used with showerheads 300 has been illustrated in disclosed, it is to be understood that enclosure constructions as disclosed herein may comprise one or any number of material source lines as called for by the particular semiconductor fabrication assembly and associated reactors and showerheads, and that such material source lines may be routed from outside of the enclosure construction 300 to inside of the enclosure construction and to the showerheads differently than as specifically illustrated and disclosed. And, it intended that all such variations of material source lines and routing and the like that avoid the use of heat jackets within the enclosure construction are within the scope of enclosure constructions as disclosed herein.

In an example, the enclosure construction 300 may include a pressure transducer 332 or the like that is positioned and/or attached outside of the enclosure construction and that is configured to monitor or determine the pressure of one or both of material source in the source lines 324 and 326 disposed within the enclosure construction 300. The pressure transducer 332 is positioned outside of the enclosure construction 300 to avoid exposure to the heated air being circulated within the enclosure construction 300 that may otherwise adversely affect the electronics and operation of the same. In an example, the enclosure construction 300 may include a temperature sensor 334 or the like that is positioned and/or attached outside of the enclosure construction and that is configured to monitor or determine the air temperature inside enclosure construction 300. The temperature sensor 334 may be positioned outside of the enclosure construction 300 to avoid exposure to the heated air being circulated within the enclosure construction 300 that may otherwise adversely affect the electronics and operation of the same.

In an example, a controller 336 may be used for the purpose of ensuring that a desired heated temperature setting or set point is maintained within the enclosure constriction 300 during operation of the semiconductor fabrication assembly. In an example, the controller 336 may be configured to receive a desired heated temperature set point by user input or by programming, and may be configured to operate one or more of the motor 322, the heating element 314, and the cooling element 320 by wired or wireless interface to adjust temperature of the heated air being circulated within the enclosure construction based on the temperature of the heated air within the enclosure as measured or detected by the temperature sensor 334. The controller 336 may be in the form of a processor or the like that is programmed to provide output signals to one or more of the motor 322, the heating element 314, and the cooling element 320 to maintain the heated air temperature within the enclosure construction 300 at the set point temperature. In an example, the controller 336 may be programmed to provide alarm or the like, e.g., in the event that the heated air temperature within the enclosure construction 300 exceeds the set point temperature.

In the example enclosure construction 300 illustrated in FIG. 3, a temperature gradient of high temperature to low temperature is shown in the form of an arrow 340 extending upwardly inside of the enclosure construction 300 from the assembly base structure 312 towards the top lid 308. This temperature gradient illustrates that temperature within the enclosure is highest near the reactors and associated showerheads 304, reflecting the fact that the reactors and associated showerheads 304 are operated under heated temperature conditions of from about 50° C. to 150° C. during operation, and that the temperature decreases moving upwardly away from the showerheads 304. The temperature gradient 340 helps to illustrate the existence of a number of different heat zones in the semiconductor fabrication assembly (without heated air circulation in an enclosed environment) produced by the different components disposed therein, such as the reactors, associated showerheads, and source lines, that are operated at different temperatures and that otherwise presents a challenge to maintaining the proper operating temperatures of such components in the different heater zones through the use of controls, heating devices such as heating jacket, and/or insulation (as used in conventional semiconductor fabrication apparatus not making use of the enclosure construction as disclosed herein).

FIG. 4 illustrates the example enclosure construction 300 as illustrated in FIG. 3, which includes all of the elements and features noted above. FIG. 4 additionally illustrates example heated air circulation flow paths 342 within the enclosure construction 300. In an example, to minimize the existence the thermal gradient disclosed above and illustrated in FIG. 3, the enclosure construction 300 is configured to operate the fan impeller 316 to cause air to flow downwardly within the enclosure construction 300 and onto the heat element 314. In an example, the enclosure construction 300 comprises one or more cowlings or baffles 344 disposed therein that are configured and oriented to assist in directing air flow from the fan impeller 316 downwardly and outwardly towards and over the showerheads 304. As the air flow passes over the showerheads 304 it circulated upwardly within the enclosure construction 300 towards the top lid 308 where the heated air passes over the material source lines 324 and 326 and is directed inwardly towards a center portion of the enclosed container and the cooling element 320. The heated air is then passed over and/or through the cooling element 320 and is directed downwardly towards an intake side 346 of the fan impeller 316. As illustrated, the one or more cowlings or baffles 344 also function to create an intake plenum within the enclosure construction 300 for directing the air from the cooling element 320 to the fan impeller 316 for recirculation in the manner described to perpetuate the heated air circulation flow paths 342 within the enclosure construction 300.

A feature of the enclosure construction as disclosed above is specially configured to attach with a semiconductor fabrication assembly or apparatus and enclose the above-described components disclosed therein to produce a heated air circulation path 342 that operates to minimize or eliminate the otherwise existing heated air temperature gradient, and provide a uniformly heated air temperature therein that operates to maintain the material source lines 324 and 326 at a desired heated temperature without the need for using heating jackets and the like otherwise needed in conventional semiconductor fabrication assemblies or apparatus having multiple heater zones and components exposed to the external environment. Avoiding the need for such heater jackets, controllers for the same, and insulation associated with using the heater jackets, provides a semiconductor fabrication assembly or apparatus that can be assembled, maintained, and repaired in an easier and more timely fashion (due to both the reduced spatial density and the reduced number of additional parts or elements) as compared with conventional semiconductor fabrication assemblies or apparatus not comprising the enclosure construction as disclosed herein. A further feature of the enclosure construction as disclosed above is that it operates to minimize or prevent thermal energy or heat loss to the external environment, thereby improving the thermal efficiency of the semiconductor fabrication assembly or apparatus.

Although an example enclosure construction as used with semiconductor fabrication assemblies or apparatus has been disclosed in detail above, those skilled in the art will readily appreciate that many modifications are possible in the example embodiments without materially departing from the intent and purpose of the example enclosure constructions as disclosed herein. Accordingly, all such modifications of enclosure constructions are intended to be included within the scope of this disclosure as defined in the following claims.

What is claimed is:

1. A heating assembly for a plurality of reactors used for semiconductor fabrication, comprising:
a housing configured to fit over and enclose at least an upper chamber of the plurality of reactors and associated showerheads and gas lines used for semiconductor fabrication;
a heating element disposed in the housing and configured to provide heat within the housing; and
a fan impeller disposed in the housing and configured to distribute the heat produced by the heating element throughout the housing;
wherein the heating element and the fan impeller are operated to provide temperature uniformity within the housing.

2. The heating assembly of claim 1, wherein the housing is thermally insulated to minimize heat loss from inside the housing to an external environment.

3. The heating assembly of claim 1, comprising a fan motor operatively connected with the fan impeller, wherein the fan motor is disposed outside of the housing.

4. The heating assembly of claim 1, wherein the plurality of reactors are attached to a base, wherein the housing is the form of a box having side walls attached to a top lid forming an enclosure, and wherein an open end of the housing formed by the side walls is attached with the base.

5. The heating assembly of claim 1, wherein the housing comprises one or more openings for accommodating passage of source pipes therein.

6. The heating assembly of claim 1, comprising a sensor disposed in the housing for monitoring the temperature within the housing.

7. The heating assembly of claim 1, comprising a controller for adjusting one or both of the heat produced by the heating element and a speed of the fan impeller.

8. The heating assembly of claim 1, wherein the housing comprises one or more elements disposed therein for channeling the heat moved by the fan within the housing in a desired direction.

9. The heating assembly of claim 8, wherein the one or more elements are baffles that direct the heat moved by the fan to the one or more showerheads.

10. An apparatus, comprising:
a housing having wall surfaces and a lid forming an enclosure configured to enclose a plurality of reactors and associated showerheads and a plurality of gas lines, the housing having an open end that is attached with a base structure configured to accommodate the plurality of reactors, associated showerheads, and gas lines;
a heat source disposed in the housing and configured to produce heat;
a fan impeller disposed in the housing and configured to move the heat produced by the heat source within the housing, wherein the fan impeller is operatively connected with a motor configured to actuate the fan impeller, wherein the motor is disposed outside of the housing; and
a sensor configured to sense a temperature within the housing;
wherein the heat source and the fan impeller are positioned within the housing, and wherein one or both of the heat source and the fan impeller operated by a controller based on the temperature within the housing as detected by the sensor to maintain a set temperature in the housing during operation of the plurality of reactors.

11. The apparatus of claim 10, wherein the housing is thermally insulated to minimize heat loss to an external environment.

12. The apparatus of claim 10, wherein the heating element and the fan impeller are operated to provide a uniform temperature within the housing.

13. The apparatus of claim 10, wherein the heat source is a radiant heat element.

14. The apparatus of claim 10, wherein the housing is configured to be disposed over at least an upper chamber of each reactor.

15. The apparatus of claim 10, further comprising one or more baffles in the housing that are configured to direct heat moved by the fan impeller downwardly to the plurality of reactors before subsequent upward movement back to the fan impeller.

16. A method for externally heating a plurality of reactors, associated showerheads, and gas lines used for semiconductor fabrication, the method comprising the steps of:
producing heat within a housing that encloses at least an upper chamber of the plurality of reactors, the associated showerheads, and the gas lines, wherein the heat is produced by a heat source disposed within the housing; and
distributing the heat produced by the heat source within the housing by a fan impeller disposed within the housing.

17. The method of claim 16, wherein during the step of distributing, the heat moved by the fan impeller is directed by one or more baffles disposed in the housing to at least one of the reactors before being directed back to the fan impeller.

18. The method of claim 16, comprising operating one or both of the heat source or the fan impeller to provide a uniform temperature within the housing.

19. The method of claim 18, comprising detecting a temperature within the housing through the use of a sensor disposed in the housing and operating the heat source and fan impeller based on the detected temperature.
